(19) United States
(12) Patent Application Publication
(10) Pub. No.: US 2008/0218952 A1
(43) Pub. Date: Sep. 11, 2008

(54) Flat Screen Television Unit

(76) Inventor: Alastair Benn, Herts (GB)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(21) Appl. No.: 11/568,222

(22) PCT Filed: May 23, 2005
(86) PCT No.: PCT/GB05/02027

§ 371 Date: Apr. 22, 2008

(30) Foreign Application Priority Data
May 29, 2004 (GB) 0412092.9

(51) Int. Cl. H05K 5/02

(52) U.S. Cl. 361/681

(57) ABSTRACT

A flat screen television unit comprises a mounting plate (4) adapted to be surface mounted to, or inserted into, a receiving component, such as a wall (3) or door, and secured in position; a TV screen assembly (7) of dimensions such that it may be fitted to, or into, the mounting plate (4) and secured directly thereto; a first component (14) of a magnetic catch carried by the mounting plate; and a second component (17) of a magnetic catch carried by an outer glass cover sheet (15) whereby the glass cover sheet (15) is attached magnetically to the mounting plate (4).

### FIELD OF THE INVENTION

This invention relates to a flat screen television unit of the kind adapted to be inset into a wall for instance, or into another item such as a door of a wardrobe or kitchen unit.

### BACKGROUND OF THE INVENTION

In PCT/GB02/02944 is described a flat screen television unit particularly adapted to be inset into a bathroom wall, with a rectangular portion of the wall chopped out to accommodate a back box, into which is inserted and secured a carrier plate provided at one side with a TV monitor, and at the other side with a glass screen. The carrier plate is secured to the back box by VELCRO™ whilst the screen is secured to the carrier plate by adhesive. Sealant must then be applied around the screen to effect a waterproof seal between the screen and the back box.

### OBJECT OF THE INVENTION

A basic object of the present invention is the provision of an improved flat screen television unit.

### SUMMARY OF THE INVENTION

According to the present invention there is provided a flat screen television unit comprising:
(i) a mounting plate adapted to be surface mounted to, or inserted into, a receiving component, such as a wall or door, and secured in position;
(ii) A TV screen assembly of dimensions such that it may be fitted to, or into, the mounting plate and secured directly thereto;
(iii) a first component of a magnetic catch carried by the mounting plate; and
(iv) a second component of a magnetic catch carried by an outer glass cover sheet whereby the glass cover sheet is attached magnetically to the mounting plate.

### ADVANTAGES OF THE INVENTION

Compared with the prior art proposal described above, the flat screen TV unit of the invention simplifies the installation and reduces component costs. In addition, the prior art housing, carrying the monitor and front plate, has been eliminated, as has the need for the glass cover sheet to be siliconed around its perimeter. In practice, installation by insetting into a wall for instance, is simply by fixing the mounting plate into the wall (e.g. using mounting brackets), after excavating a recess of suitable width, height and depth, fixing the TV screen assembly to the mounting plate, and finally attaching the glass cover sheet to the mounting plate by the magnetic catches to close off the front of the mounting plate, the arrangement and relative dimensions being such that the magnetic attraction partially compresses the sealant, causing it to be watertight.

### PREFERRED OR OPTIONAL FEATURES

The mounting plate is of sheet metal.

The mounting plate is produced as a sheet metal pressing.

The mounting plate is rectangular in front and rear elevation.

The mounting plate has a back wall provided with a location means for positionally locating the TV screen assembly with respect to the mounting plate.

The location means is an aperture.

The mounting plate has an inner perimeter wall extending orthogonally from the mounting plate.

The mounting plate has a flange extending outwardly from a terminal end of the inner perimeter wall and orthogonally thereto.

The mounting plate has an outer perimeter wall extending from a terminal end of the flange, and parallel to the inner perimeter wall.

The mounting plate carries, at selected locations, one half of a plurality of magnetic catches.

The one half is a magnet.

The flange is provided with a waterproof seal or sealant against which bears an inner face of the glass cover sheet.

The seal or sealant is resilient.

The inner face of the glass cover sheet carries, at corresponding locations the other half of the magnetic catches.

The other half is a metallic attractor.

The mounting plate is provided with an outer perimeter flange, e.g. of 8 mm width, which serves to hide any chipped or jagged tile edges which may exist in a (tiled) bathroom installation, or wood in cupboard installations.

For kitchen or bathroom installation in a tiled wall, the mounting plate is ideally of dimensions representing a multiple number of industry-standard sized wall tiles, e.g. 450×600 mm.

The glass cover sheet is provided with magnets, or ferromagnetic material at specific locations.

The magnets etc are secured to the glass screen by adhesive.

The locations are four in number, in the vicinity of each corner of a rectangular screen.

For installation in a kitchen cupboard for instance, no second flange is required on the mounting plate, and the dimensions of the unit would be such that installation in industry-standard 500 mm or 600 mm kitchen units is readily possible.

### BRIEF DESCRIPTION OF THE DRAWINGS

One example of flat screen television unit in accordance with the invention is shown diagrammatically in the accompanying drawings, in which

FIG. 1 is a diagrammatic side elevation of a flat screen television unit in accordance with the invention set into a wall e.g. of a bathroom;

FIG. 2 is an exploded view of three basic components being the mounting plate, the TV screen assembly and the cover sheet;

FIG. 3 is a side elevation assembled flat screen TV unit of FIG. 2; and

FIG. 4 is a front elevation of FIG. 3.

### DETAILED DESCRIPTION OF THE DRAWINGS

In the drawings, a flat screen television unit 1 is set into a suitable recess 2 in a wall 3 e.g. of a bathroom.

The unit 1 comprises a mounting plate 4 produced as a sheet metal pressing, being rectangular in front and rear elevation, and comprising a back wall 5 provided with an aperture 6 which serves as a location means for a TV screen assembly 7.

From the back wall 5 extends orthogonally an inner perimeter wall 8, whilst a flange 9 extends outwardly and orthogonally from a terminal end of the inner perimeter wall 8.

From a terminal end of the flange 9 extends orthogonally, and parallel to the inner perimeter wall 8, extends an outer perimeter wall 10.

From a terminal end of the outer perimeter wall 10, a flange or bezel 11 extends parallel to the back wall 5 and flange 9, behind which flange or bezel 10 an upper edge of a bathroom tile 12 may be located.

The back wall 5 carries on its inner surface 13, four magnets 14, one located towards each corner of the mounting plate 4.

A rectangular, glass cover sheet 15 is so dimensioned to be a close fit within the outer perimeter wall 10. Inner surface 16 of the cover sheet 15 carries four ferromagnetic attractors 17 at generally corner locations corresponding to the magnets 14, so that magnetic attraction secures the glass cover sheet 15 to the mounting plate 4.

Also on the inner surface 16 of the glass cover sheet 15 is provided, around the entire perimeter, a layer of resilient waterproof sealant 18, adapted to be slightly deformed upon engagement with the flange 9 when the attractors 17 are engaged with the magnets 14, whereby the components of the TV screen assembly 7 are protected from possible damage by water droplets or water vapour to be found in a bathroom.

For a kitchen location in contrast to a bathroom location, the flange or bezel 11 could be omitted.

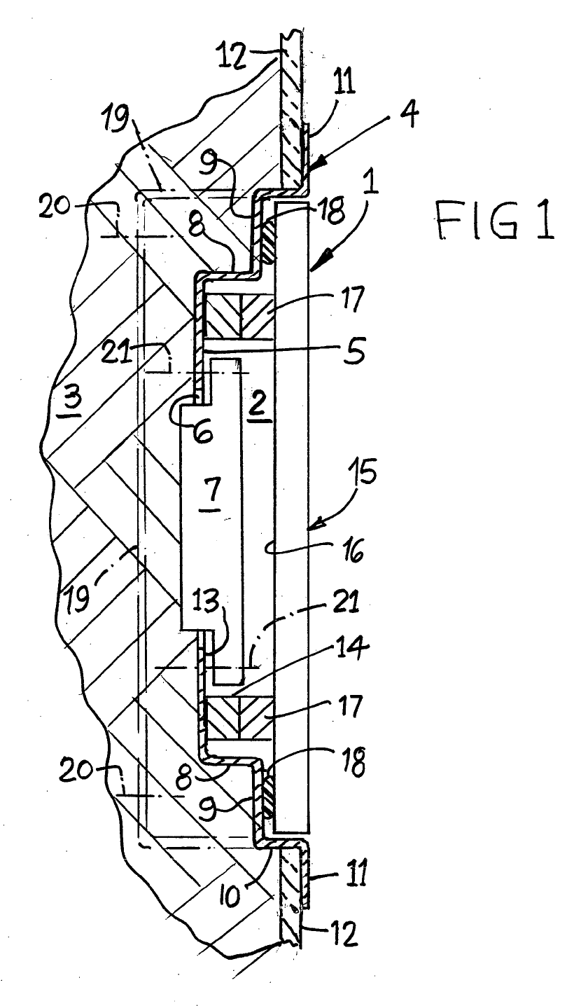

FIG. 1 illustrates an inset location, which involves chopping out a suitably profiled recess 2 in the wall 3, to achieve an aesthetically attractive flush finish. In some circumstances, it may not be practical or possible e.g. because of pipework or wiring within the wall 3, or possibly a concrete wall construction, to chop out a recess 2. In such circumstances, the mounting plate 4 would be formed into a closed box having a rear wall shown in chain-dotted line at 19 provided with four apertures to receive four securing screws along axes 20 into drilled and plugged holes in the wall 3, such that the “boxed” unit stands proud of the wall 3, in the manner of a bathroom, or kitchen, cabinet, whilst the TV screen assembly 20 is attachable to the mounting plate 4 by e.g. four screws on axes 21.

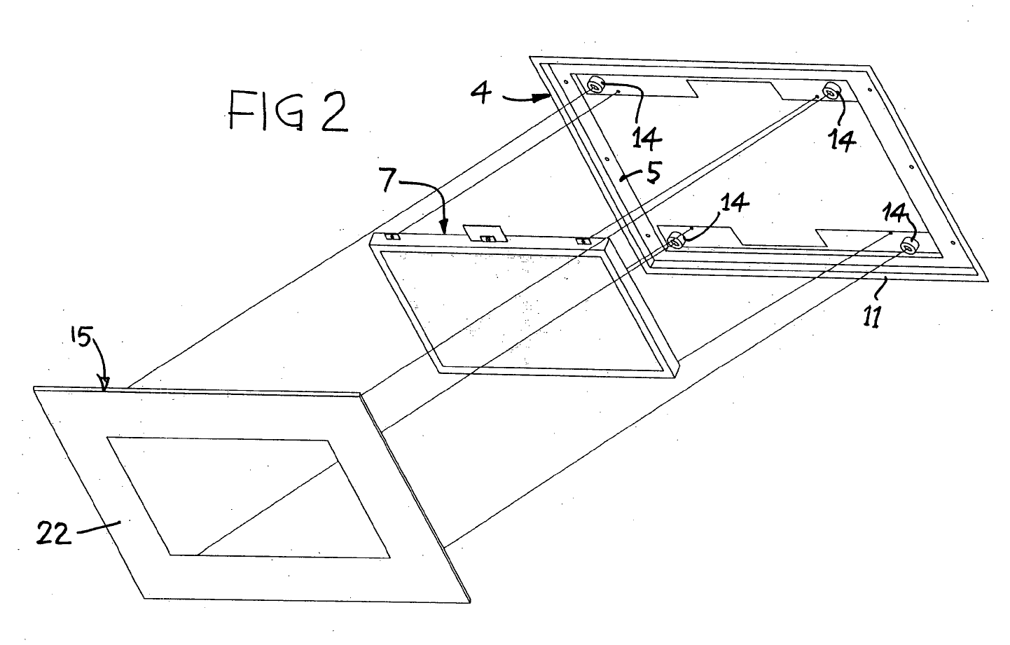

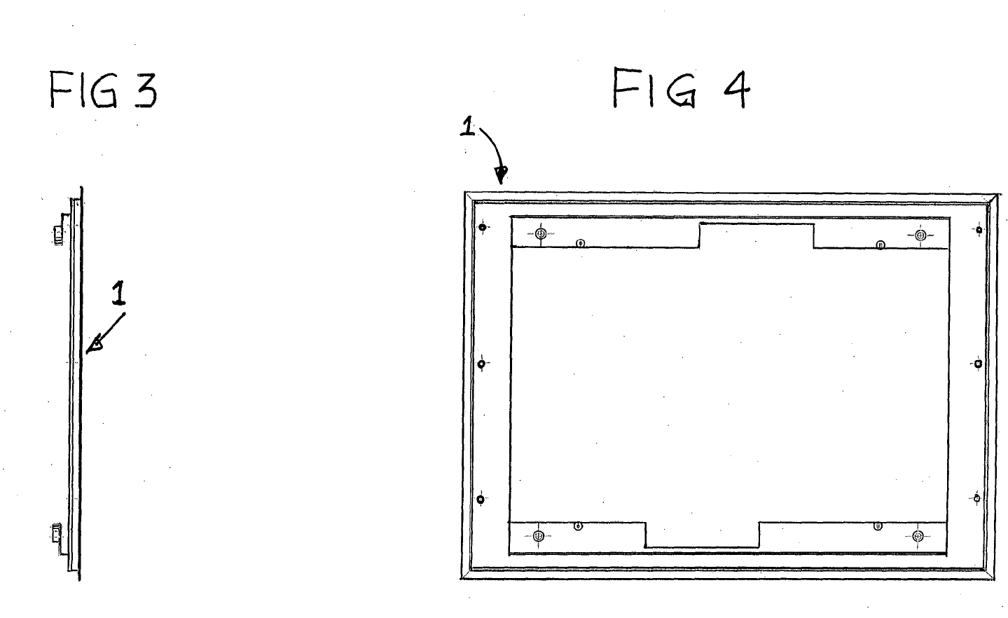

As indicated in FIG. 2, the glass cover sheet 15 may be mounted in a rectangular metal frame 22.

1. A flat screen television unit comprising:
(i) a mounting plate adapted to be surface mounted to, or inserted into, a receiving component, such as a wall or door, and secured in position;
(ii) a TV screen assembly of dimensions such that it may be fitted to, or into, one side of said mounting plate and secured directly thereto;
(iii) a first component of a magnetic catch carried by said side of said mounting plate; and
(iv) a second component of said magnetic catch carried by said one side of an outer glass cover sheet, whereby said glass cover sheet is attached magnetically to said side of said mounting plate so as to cover said TV screen, with a waterproof seal or sealant between an inner face of said glass cover sheet and said mounting plate.

2. A flat screen television unit as claimed in claim 1, wherein said mounting plate is of sheet metal.

3. A flat screen television unit as claimed in claim 1, wherein said mounting plate is produced as a sheet metal pressing.

4. A flat screen television unit as claimed in claim 1, wherein said mounting plate is rectangular in both front and rear elevations.

5. A flat screen television unit as claimed in claim 1, wherein said mounting plate has a back wall provided with a location means for positionally locating said TV screen assembly with respect to said mounting plate.

6. A flat screen television unit as claimed in claim 5, wherein said location means is an aperture.

7. A flat screen television unit as claimed in claim 1, wherein said mounting plate has an inner perimeter wall extending orthogonally from said mounting plate.

8. A flat screen television unit as claimed in claim 7, wherein said mounting plate has a flange extending outwardly from a terminal end of said inner perimeter wall and orthogonally thereto.

9. A flat screen television unit as claimed in claim 8, wherein said mounting plate has an outer perimeter wall extending from a terminal end of said flange, and parallel to said inner perimeter wall.

10. A flat screen television unit as claimed in claim 1, wherein said mounting plate carries, at selected locations, one half of a plurality of said magnetic catches.

11. A flat screen television unit as claimed in claim 10, wherein said one half is a magnet.

12. A flat screen television unit as claimed in claim 8, wherein said flange is provided with said waterproof seal or sealant against which bears an inner face of said glass cover sheet.

13. A flat screen television unit as claimed in claim 1, wherein said seal or sealant is resilient, being partially compressed by magnetic attraction of said magnetic catch.

14. A flat screen television unit as claimed in claim 11, wherein said inner face of said glass cover sheet carries, at corresponding locations, the other half of said magnetic catches.

15. A flat screen television unit as claimed in claim 11, wherein said other half is a metallic attractor.

16. A flat screen television unit as claimed in claim 1, wherein said mounting plate is provided with an outer perimeter flange.

17. A flat screen television unit as claimed in claim 1, in an embodiment for kitchen or bathroom installation in a tiled wall, wherein said mounting plate is of dimensions representing a multiple number of industry-standard sized wall tiles.

18. A flat screen television unit as claimed in claim 1, wherein said glass cover sheet is provided with a plurality of magnets, or with ferromagnetic material, at specific locations.

19. A flat screen television unit as claimed in claim 18, wherein said magnets or said ferromagnetic material is secured to said glass screen by adhesive.

20. A flat screen television unit as claimed in claim 18, wherein, with a rectangular glass cover sheet, said locations are four in number, in the vicinity of each corner of said rectangular sheet.
